(19) United States
(12) Patent Application Publication
(10) Pub. No.: US 2025/0191895 A1
(43) Pub. Date: Jun. 12, 2025

(54) FLOWRATE CONTROL UNIT FOR TEMPERATURE ADJUSTMENT AND SEMICONDUCTOR MANUFACTURING DEVICE

(71) Applicants: CKD CORPORATION, Komaki-shi, Aichi (JP); TOKYO ELECTRON LIMITED, Tokyo (JP)

(72) Inventors: Yuko SUZUKI, Komaki-shi (JP); Keiichi NISHIKAWA, Komaki-shi (JP); Naofumi YOSHIDA, Komaki-shi (JP); Keisuke YOSHIMURA, Kurokawa-gun (JP); Takuya KATAGIRI, Kurokawa-gun (JP); Ryo MURAKAMI, Kurokawa-gun (JP)

(73) Assignees: CKD CORPORATION, Komaki-shi, Aichi (JP); TOKYO ELECTRON LIMITED, Tokyo (JP)

(21) Appl. No.: 18/856,129

(22) PCT Filed: Mar. 31, 2023
(86) PCT No.: PCT/JP2023/013492

§ 371 Date: Oct. 11, 2024

(30) Foreign Application Priority Data
Apr. 26, 2022 (JP) 2022-072310

(51) Int. Cl. H01J 37/32

(52) U.S. Cl. CPC H01J 37/32724; H01J 2237/002; H01J 2237/24585; H01J 2237/3341

(57) ABSTRACT

According to the present invention, when the current temperature of a fluid for post-circulation temperature control is lower than a second temperature, the temperature of the fluid for temperature control is adjusted on the basis of a first temperature control value indicating a temperature (fourth temperature) higher than the second temperature until the current temperature rises to a prescribed threshold value (third temperature) lower than the second temperature. When the current temperature has risen to the threshold value (third temperature), the temperature of the fluid for temperature control is adjusted on the basis of a second temperature control value indicating a temperature equal to the second temperature.

### CROSS-REFERENCE TO RELATED APPLICATIONS

This is a national phase application filed under 35 U.S.C. 371 of PCT/JP2023/013492 filed on Mar. 31, 2023, which claims the benefit of priority from the prior Japanese Patent Application No. 2022-072310 filed on Apr. 26, 2022, the entire contents of all of which are incorporated herein by reference.

### TECHNICAL FIELD

The present invention relates to a flowrate control unit for temperature adjustment to adjust a temperature of a susceptor from a prescribed first temperature to a prescribed second temperature by circulating a temperature control fluid to the susceptor provided in a semiconductor manufacturing device and relates to a semiconductor manufacturing device provided with this flowrate control unit for temperature adjustment.

### BACKGROUND ART

A plasma processing device of RIE (Reactive Ion Etching) type, which is used

for manufacturing a semiconductor, introduces process gas in a processing container to perform etching process of a wafer that is held by the susceptor inside the processing container. For the etching process, a plurality of types of process gases are used, and different processing conditions are set for each process gas. The processing conditions include a temperature of the wafer as an object to be processed, and therefore a temperature control of the susceptor holding the wafer is carried out so that the temperature of the wafer meets the processing conditions.

Herein, as a technique of controlling the temperature of the susceptor, a flowrate control unit for temperature adjustment to adjust a temperature of a susceptor by circulating a temperature control fluid in the susceptor as disclosed in Patent Document 1 has been known. The flowrate control unit for temperature adjustment according to this conventional technique adjusts the temperature of the susceptor as shown in FIG. 6. FIG. 6 is a graph showing a relation between a temperature of a temperature control fluid and a temperature of a susceptor in a flowrate control unit for temperature adjustment according to the conventional art. A waveform C4 represents a temperature control value for controlling the temperature of the temperature control fluid when the temperature of the susceptor is to be adjusted to a second temperature T12. A waveform W71 represents temperature changes in the temperature control fluid that is input to the susceptor by the flowrate control unit for temperature adjustment. A waveform W81 represents temperature changes in the susceptor.

For example, when the temperature of the susceptor is to be increased from a first temperature T11 to the second temperature T12, which is higher than the first temperature T11 by ΔTa, for switching process gases, the flowrate control unit for temperature adjustment according to the conventional art creates a temperature control value for directing the temperature of the temperature control fluid to be equal to the second temperature T12 as indicated by the waveform C4 in FIG. 6. Then, based on this temperature control value, the temperature of the temperature control fluid that is to be input to the susceptor is regulated to be equal to the second temperature T12 of the susceptor (the waveform W71). Thereby, the susceptor is heated by the temperature control fluid that has been at the second temperature T12, and thus the temperature of the susceptor increases to the second temperature T12 as time elapses (the waveform W81).

### RELATED ART DOCUMENTS

### Patent Documents

Patent Document 1: JP2020-160731A

### SUMMARY OF INVENTION

### Problems to be Solved by the Invention

The flowrate control unit for temperature adjustment according to the conventional art has a problem of requiring time for adjusting the temperature of the susceptor. Herein, FIG. 7 is a table illustrating a period of time for the temperature of the susceptor to reach the second temperature T12 (a period of time ΔXf from a time point X1 to a time point X5 in FIG. 6) for each value ΔTa as a gap of the first temperature T11 and the second temperature T12. For example, a value of 25 seconds with ΔTa of 30° C. and a target temperature (the second temperature T12) of 40° C. means that the period of time ΔXf for the temperature of the susceptor to be increased by 30° C. to reach 40° C. (namely, the temperature of the susceptor is increased from 10° C. to 40° C.) is 25 seconds. Herein, ΔTa is exemplified as 30° C. and 40° C. in the table since ΔTa is in a range of 30 to 40° C. in most cases under a general processing condition of etching process, and it is only an exemplification.

When ΔTa is 30° C. or 40° C., the period of time ΔXf is 25 to 48 seconds as shown in FIG. 7. If it takes long time every time switching the process gases, a period of time would accumulate in response to types of process gases and the number of processing conditions, which could cause loss of several minutes per every etching process for one piece of wafer, and thereby, degradation of efficiency in semiconductor manufacturing is concerned.

The present invention has been made in view of the above problem and has a purpose of providing a flowrate control unit for temperature adjustment achieving high-speed adjustment of a temperature of a susceptor.

### Means of Solving the Problems

To achieve the above purpose, a flowrate control unit for temperature adjustment according to one aspect of the present invention has the following configuration.

The flowrate control unit for temperature adjustment according to one aspect of the invention is a flowrate control unit for temperature adjustment to adjust a temperature of a susceptor from a prescribed first temperature to a prescribed second temperature by circulating a temperature control fluid through the susceptor provided in a semiconductor manufacturing device, wherein the unit comprises: an output pipe to output the temperature control fluid to the susceptor; a first temperature measuring part to measure a temperature of the temperature control fluid output from the output pipe; an input pipe to input a post-circulation temperature control fluid, which is the temperature control fluid output from the output pipe to the susceptor and circulated through the susceptor; a control device to create a temperature control value for directing the temperature of the temperature control fluid output from the output pipe; a fluid control part to adjust the temperature of the temperature control fluid output from the output pipe based on the temperature control value; and a second temperature measuring part to measure a current temperature of the post-circulation temperature control fluid, wherein the temperature control value includes a prescribed first temperature control value for directing a temperature higher than the second temperature and a prescribed second temperature control value for directing the temperature equal to the second temperature, and the fluid control part is configured to: perform first adjusting to adjust the temperature of the temperature control fluid by the first temperature control value until a current temperature increases to a prescribed threshold value, which is lower than the second temperature, when the current temperature is lower than the second temperature; and perform second adjusting to adjust the temperature of the temperature control fluid by the second temperature control value when the current temperature increases to the threshold value.

Further, in the above-mentioned flowrate control unit for temperature adjustment, preferably, the temperature control value in the second adjusting gradually changes from the first temperature control value to the second temperature control value.

Further, in the above-mentioned flowrate control unit for temperature adjustment, preferably, the fluid control part includes a low-temperature pipe through which a low-temperature fluid for lowering the temperature of the temperature control fluid flows, a high-temperature pipe through which a high-temperature fluid for increasing the temperature of the temperature control fluid flows, and a spool valve connected to the output pipe, the input pipe, the low-temperature pipe, and the high-temperature pipe, and the fluid control part is configured to control a flow rate distribution ratio of the post-circulation temperature control fluid, the low-temperature fluid, and the high-temperature fluid to adjust the temperature of the temperature control fluid output from the output pipe.

Further, in the above-mentioned flowrate control unit for temperature adjustment, preferably, the input pipe includes a pump to circulate the temperature control fluid, and the second temperature measuring part is provided on an upstream side of the pump.

Further, in the above-mentioned flowrate control unit for temperature adjustment, preferably, the flowrate control unit for temperature adjustment further comprises a joint pipe joining the input pipe and the susceptor, and the second temperature measuring part is provided in the joint pipe.

The above-mentioned flowrate control unit for temperature adjustment measures the current temperature of the post-circulation temperature control fluid by the second temperature measuring part. The post-circulation temperature control fluid is a temperature control fluid that has circulated through the susceptor, and thus the temperature can be identified with the temperature of the susceptor. For example, a susceptor in an RIE plasma processing device is hard to directly measure a temperature due to an influence of process gas that has been brought into a plasma state, and others. To address this, the temperature of the susceptor can be stably monitored by measuring the current temperature of the post-circulation temperature control fluid circulated through the susceptor.

Further, when the current temperature of the post-circulation temperature control fluid (i.e., the temperature of the susceptor) is lower than the second temperature, the above-mentioned flowrate control unit for temperature adjustment adjusts the temperature of the temperature control fluid (the first adjusting) by the prescribed first temperature control value, which directs the higher temperature than the second temperature, until the current temperature of the post-circulation temperature control fluid (the temperature of the susceptor) increases to the prescribed threshold value lower than the second temperature so that the temperature of the susceptor is adjusted to the prescribed second temperature. Thus, the susceptor is heated by the temperature control fluid at the higher temperature than the second temperature, and thus the temperature of the susceptor increases toward the second temperature from the first temperature at high speed. Then, when the current temperature of the post-circulation temperature control fluid (the temperature of the susceptor) increases to the threshold value, the temperature of the temperature control fluid is adjusted (the second adjusting) by the second temperature control value, which directs the equal temperature with the second temperature, so that the temperature of the susceptor can be stabilized to the second temperature.

Herein, the prescribed first temperature control value is explained. The higher the first temperature control value is set than the second temperature, the faster the temperature of the susceptor increases from the first temperature to the second temperature. Accordingly, the first temperature control value is appropriately set in accordance with a target period of time for increasing the temperature of the susceptor from the first temperature to the second temperature.

Further, the prescribed first temperature, the prescribed second temperature, and the prescribed threshold value are explained. For example, in a process of performing etching process for a wafer by an RIE plasma processing device, when a processing condition is to be changed from a first condition to a second condition for switching process gases, the prescribed first temperature is a target temperature of the susceptor under the first condition, and the prescribed second temperature is a target temperature of the susceptor for the second condition. Further, the prescribed threshold value is set to a temperature, at which the process under the second condition can be started even before the temperature of the susceptor reaches the second temperature, while the condition is shifted from the first condition to the second condition.

Further, a flowrate control unit for temperature adjustment according to another aspect of the invention has the following configuration.

The flowrate control unit for temperature adjustment according to another aspect of the invention is a flowrate control unit for temperature adjustment to adjust a temperature of a susceptor from a prescribed first temperature to a prescribed second temperature by circulating a temperature control fluid through the susceptor provided in a semiconductor manufacturing device, wherein the unit comprises: an output pipe to output the temperature control fluid to the susceptor; a first temperature measuring part to measure a temperature of the temperature control fluid output from the output pipe; an input pipe to input a post-circulation temperature control fluid, which is a temperature control fluid output from the output pipe to the susceptor and circulated through the susceptor; a control device to create a temperature control value for directing the temperature of the temperature control fluid output from the output pipe, a fluid control part to adjust the temperature of the temperature control fluid output from the output pipe based on the temperature control value; and a second temperature measuring part to measure a current temperature of the post-circulation temperature control fluid, wherein the temperature control value includes a prescribed first temperature control value for directing a temperature lower than the second temperature and a prescribed second temperature control value for directing the temperature equal to the second temperature, and the fluid control part is configured to: perform first adjusting to adjust the temperature of the temperature control fluid by the first temperature control value until the current temperature is lowered to a prescribed threshold value, which is higher than the second temperature, when the current temperature is higher than the second temperature; and perform second adjusting to adjust the temperature of the temperature control fluid by the second temperature control value when the current temperature is lowered to the threshold value.

Further, in the above-mentioned flowrate control unit for temperature adjustment, preferably, the temperature control value in the second adjusting gradually changes from the first temperature control value to the second temperature control value.

Further, in the above-mentioned flowrate control unit for temperature adjustment, preferably, the fluid control part includes a low-temperature pipe through which a low-temperature fluid for lowering the temperature of the temperature control fluid flows, a high-temperature pipe through which a high-temperature fluid for increasing the temperature of the temperature control fluid flows, and a spool valve connected to the output pipe, the input pipe, the low-temperature pipe, and the high-temperature pipe, and the fluid control part is configured to control a flow rate distribution ratio of the post-circulation temperature control fluid, the low-temperature fluid, and the high-temperature fluid to adjust the temperature of the temperature control fluid output from the output pipe.

Further, in the above-mentioned flowrate control unit for temperature adjustment, preferably, the input pipe includes a pump to circulate the temperature control fluid, and the second temperature measuring part is provided on an upstream side of the pump.

Further, in the above-mentioned flowrate control unit for temperature adjustment, preferably, the flowrate control unit for temperature adjustment further comprises a joint pipe joining the input pipe and the susceptor, and the second temperature measuring part is provided in the joint pipe.

The above-mentioned flowrate control unit for temperature adjustment measures the current temperature of the post-circulation temperature control fluid by the second temperature measuring part. The post-circulation temperature control fluid is the temperature control fluid that has circulated through the susceptor, and thus the temperature can be identified with the temperature of the susceptor. For example, a susceptor in an RIE plasma processing device is hard to directly measure the temperature due to influence of process gas that has brought into a plasma state, and others. To address this, the temperature of the susceptor can be stably monitored by measuring the current temperature of the post-circulation temperature control fluid circulated through the susceptor.

Further, when the current temperature of the post-circulation temperature control fluid (i.e., the temperature of the susceptor) is higher than the second temperature, the above-mentioned flowrate control unit for temperature adjustment adjusts the temperature of the temperature control fluid (the first adjusting) by the prescribed first temperature control value, which directs the lower temperature than the second temperature, until the current temperature of the post-circulation temperature control fluid (the temperature of the susceptor) is lowered to the prescribed threshold value that is higher than the second temperature so that the temperature of the susceptor is adjusted to the prescribed second temperature. Thus, the susceptor is cooled by the temperature control fluid at the lower temperature than the second temperature, and thus the temperature of the susceptor is lowered toward the second temperature from the first temperature at high speed. Then, when the current temperature of the post-circulation temperature control fluid (the temperature of the susceptor) is lowered to the threshold value, the temperature of the temperature control fluid is adjusted (the second adjusting) by the second temperature control value directing the equal temperature with the second temperature, so that the temperature of the susceptor can be stabilized to the second temperature.

Herein, the prescribed first temperature control value is explained. The lower the first temperature control value is set than the second temperature, the faster the temperature of the susceptor is lowered from the first temperature to the second temperature. Accordingly, the first temperature control value is appropriately set in accordance with a target period of time for lowering the temperature of the susceptor from the first temperature to the second temperature.

Further, the prescribed first temperature, the prescribed second temperature, and the prescribed threshold value are explained. For example, in a case of performing etching process for a wafer by an RIE plasma processing device, when a processing condition is to be changed from a first condition to a second condition for switching process gases, the prescribed first temperature is a target temperature of the susceptor under the first condition, and the prescribed second temperature is a target temperature of the susceptor for the second condition. Further, the prescribed threshold value is set to a temperature at which the process under the second condition can be started even before the temperature of the susceptor reaches the second temperature while the condition is shifted from the first condition to the second condition.

Further, a semiconductor manufacturing device according to one aspect of the present invention to solve the above problem is provided with the susceptor and the above-mentioned flowrate control unit for temperature adjustment, which is connected to the susceptor.

### EFFECTS OF THE INVENTION

According to a flowrate control unit for temperature adjustment and a semiconductor manufacturing device of the present invention, adjustment of a temperature of a susceptor can be performed at high speed.

### BRIEF DESCRIPTION OF THE DRAWINGS

FIG. 1 is a circuit diagram of a flowrate control unit for temperature adjustment

according to an embodiment of the present invention;

FIG. 2 is a graph showing a relation between a temperature of a temperature control fluid and a temperature of a post-circulation temperature control fluid (namely, a temperature of a susceptor) in the flowrate control unit for temperature adjustment according to a first embodiment;

FIG. 3 is a graph showing a relation between the temperature of the temperature control fluid and the temperature of the post-circulation temperature control fluid (namely, the temperature of the susceptor) in the flowrate control unit for temperature adjustment according to a second embodiment;

FIG. 4 is a table showing a period of time required for the temperature of the susceptor to reach a second temperature at each value of ΔTa as a gap between a first temperature and the second temperature;

FIG. 5 is a graph showing a relation between the temperature of the temperature control fluid and the temperature of the post-circulation temperature control fluid (namely, the temperature of the susceptor) in the flowrate control unit for temperature adjustment according to a third embodiment;

FIG. 6 is a graph showing a relation between the temperature of the temperature control fluid and the temperature of the susceptor in the flowrate control unit for temperature adjustment according to a conventional art; and

FIG. 7 is a table showing a period of time required for the temperature of the susceptor to reach the second temperature at each value of ΔTa as a gap between the first temperature and the second temperature.

### MODE FOR CARRYING OUT THE INVENTION

### First Embodiment

A first embodiment of a flowrate control unit for temperature adjustment according to the present invention is now explained in detail with reference to the accompanying drawings.

### Schematic Configuration

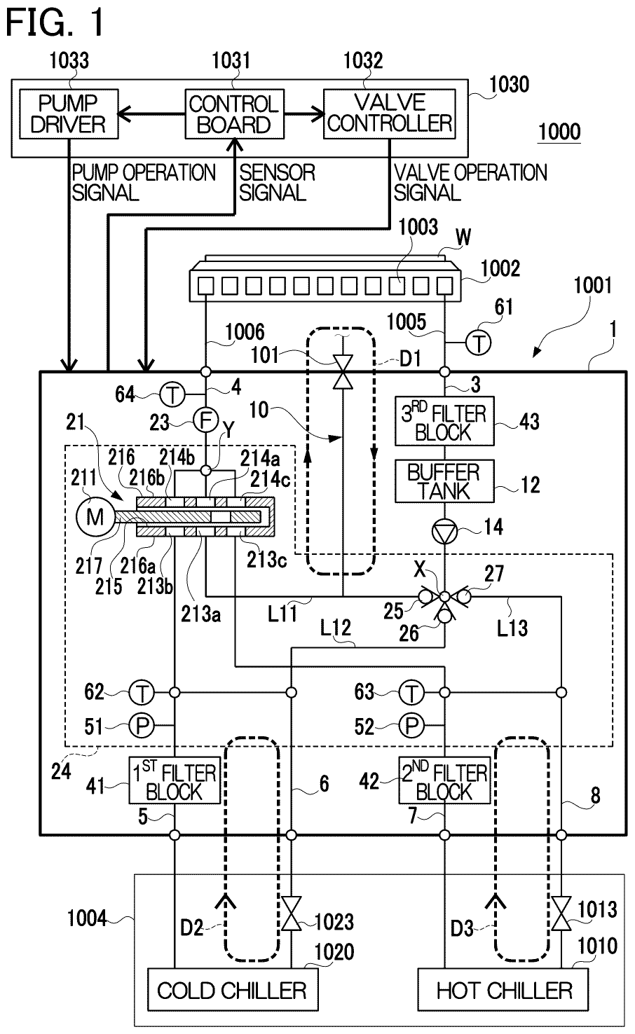

FIG. 1 is a circuit diagram of a flowrate control unit for temperature adjustment 1 (hereinafter, also referred as a “unit 1”) according to an embodiment of the present invention. The unit 1 of the present embodiment is, for example, used for a temperature control system 1001 for controlling a temperature of a semiconductor manufacturing device 1000.

The semiconductor manufacturing device 1000 of the present embodiment is configured as an RIE (Reactive Ion Etching) plasma processing device. A wafer W is placed in a susceptor 1002 disposed in a not-shown processing container, and the semiconductor manufacturing device 1000 performs etching process to the wafer W that has been controlled at a prescribed temperature.

Several types of process gases are used for the etching process, and each of the process gases is individually set with different processing conditions. The processing conditions include a temperature of the wafer W which is an object to be processed. In order to correspond the temperature of the wafer W with the processing conditions, a temperature of the susceptor 1002 holding the wafer W is controlled by the temperature control system 1001.

The temperature control system 1001 is provided with a temperature adjustment part 1003 (hereinafter, abbreviated as a “temperature control part 1003”), the unit 1, and a chiller unit 1004.

The temperature control part 1003 is provided inside the susceptor 1002 to circulate a temperature control fluid, which is output from the flowrate control unit for temperature adjustment 1, to the susceptor 1002. The temperature control fluid is fluorine inert fluid having less changes in the physical properties in a wide range of temperature. The temperature control fluid is, for example, Fluorinert™ of 3M™.

The chiller unit 1004 is provided with a cold chiller 1020 and a hot chiller 1010. The cold chiller 1020 is to circulate a low-temperature fluid that has been regulated to −30° C., for example, in order to lower a temperature of the temperature control fluid. A circulation pressure of the low-temperature fluid is controlled by a low-temperature-side control valve 1023. Further, the hot chiller 1010 is to circulate a high-temperature fluid that has been regulated to 120° C., for example, in order to increase the temperature of the temperature control fluid. The circulation pressure of the high-temperature fluid is controlled by a high-temperature-side control valve 1013.

The unit 1 can be provided with a first joint pipe 1005 to which the temperature control fluid having circulated through the susceptor 1002 (which is hereafter referred as an post-circulation temperature control fluid) is output, and a second joint pipe 1006 through which the temperature control fluid is input to the susceptor 1002. The unit 1 is connected to the susceptor 1002 by the first joint pipe 1005 and the second joint pipe 1006.

The unit 1 is provided with an input pipe 3 connected to the first joint pipe 1005, an output pipe 4 connected to the second joint pipe 1006, an input pipe for low-temperature fluid 5 and an output pipe for low-temperature fluid 6 through which the low-temperature fluid flows, an input pipe for high-temperature fluid 7 and an output pipe for high-temperature fluid 8 through which the high-temperature fluid flows, a pump 14 for circulating the temperature control fluid, a fluid control part 24, and a control device 1030. The input pipe for low-temperature fluid 5 and the output pipe for low-temperature fluid 6 are examples of the low-temperature pipe. The input pipe for high-temperature fluid 7 and the output pipe for high-temperature fluid 8 are examples of the high-temperature pipe.

On the input pipe 3, a third filter block 43, a buffer tank 12, and the pump 14 are disposed in this order from an upstream side.

The post-circulation temperature control fluid is input into the input pipe 3 from the first joint pipe 1005. Herein, on the first joint pipe 1005, a second temperature sensor 61 (one example of a second temperature measuring part) is disposed to enable measuring of the current temperature of the post-circulation temperature control fluid. The temperature control system 1001 measures the current temperature of the post-circulation temperature control fluid to obtain the current temperature of the susceptor 1002. The post-circulation temperature control fluid is a temperature control fluid after having circulated through the susceptor 1002, and thus the temperature should be identified with the temperature of the susceptor 1002. Further, the second temperature sensor 61 is disposed on the first joint pipe 1005, which means the sensor 61 is disposed on an upstream side of the pump 14. Accordingly, the temperature of the post-circulation temperature control fluid can be measured without being influenced by heat generated by the pump 14. A susceptor in an RIE plasma processing device is hard to directly measure the temperature due to influence of process gas that has been brought into a plasma state, and others, but the temperature of the susceptor 1002 can be stably monitored by measuring the current temperature of the post-circulation temperature control fluid after having circulated through the susceptor 1002. Herein, a position of disposing the second temperature sensor 61 is not necessarily limited to the first joint pipe 1005, and the sensor 61 may be disposed on the input pipe 3. However, in order to identify the current temperature of the post-circulation temperature control fluid with the current temperature of the susceptor 1002, the second temperature sensor 61 is preferably disposed in a position on the upstream side of the pump 14 and as close as possible to the susceptor 1002.

The output pipe 4 outputs the temperature control fluid to the second joint pipe 1006. On the output pipe 4, a flowrate sensor 23 and a first temperature sensor 64 (one example of a first temperature measuring part) are disposed in this order from an upstream side. The first temperature sensor 64 measures the temperature of the temperature control fluid that has been output from the output pipe 4. The fluid control part 24 is connected to the temperature control part 1003 via the input pipe 3 and the output pipe 4 so that the temperature control fluid circulates between the temperature control part 1003 and the fluid control part 24 as indicated with a broken arrow DI in FIG. 1.

The input pipe for low-temperature fluid 5 and the output pipe for low-temperature fluid 6 connect the fluid control part 24 with the cold chiller 1020 so that the low-temperature fluid is input into or output from the fluid control part 24 as indicated with a broken arrow D2 in FIG. 1. A temperature and a pressure of the low-temperature fluid that is input into the fluid control part 24 is respectively measured by a third temperature sensor 62 and a first pressure sensor 51 which are disposed on the input pipe for the low-temperature fluid 5. Further, a first filter block 41 is disposed on the input pipe for the low-temperature fluid 5, and the first filter block 41 removes foreign matters in the low-temperature fluid that is to be input into the fluid control part 24 from the input pipe for low-temperature fluid 5.

The input pipe for high-temperature fluid 7 and the output pipe for high-temperature fluid 8 connect the fluid control part 24 to the hot chiller 1010 so that the high-temperature fluid is input into or output from the fluid control part 24 as indicated with a broken arrow D3 in FIG. 1. A temperature and a pressure of the high-temperature fluid that is input into the fluid control part 24 is respectively measured by a fourth temperature sensor 63 and a second pressure sensor 52 which are disposed on the input pipe for high-pressure fluid 7. Further, a second filter block 42 is disposed on the input pipe for high-temperature fluid 7, and the second filter block 42 removes foreign matters in the high-temperature fluid that is to be input into the fluid control part 24 from the input pipe for high-temperature fluid 7.

The fluid control part 24 includes a branch point X dividing the input pipe 3 into a first branch line L11, a second branch line L12, and a third branch line 13. The first branch line L11 is connected to the spool valve 21 and provided with a first check valve 25. Further, to the first branch line L11, a purge mechanism 10 provided with a purge opening and closing valve 101 is connected so that purge air can be supplied to the unit 1 by opening the purge opening and closing valve 101 when the semiconductor manufacturing device 1000 is under maintenance, for example. The second branch line L12 is connected to the output pipe for low-temperature fluid 6 and provided with a second check valve 26. Further, the third branch line L13 is connected to the output pipe for high-temperature fluid 8 and provided with a third check valve 27.

The spool valve 21 is a well-known spool valve disclosed in JP Patent No. 5893419, for example. The spool valve 21 is provided with a drive part 211, a valve body 216, and a spool valve element 217.

The spool valve element 217 is slidably mounted in a valve chamber 215 of the valve body 216 to move inside the valve chamber 215 according to a drive force of the driving part 211.

The valve body 216 is formed with a first supply port 213a connected to the first branch line L11, a second supply port 213b connected to the input pipe for low-temperature fluid 5, and a third supply port 213c connected to the input pipe for high-temperature fluid 7 on one side surface 216a of side surfaces 216a and 216b facing each other, in a manner that the supply ports are communicated with the valve chamber 215. Further, the valve body 216 is formed on the other side surface 216b with a first discharge port 214a, a second discharge port 214b, and a third discharge port 214c to be communicated with the valve chamber 215.

The spool valve 21 changes a flow area of opening the first supply port 213a to the first discharge port 214a, a flow area of opening the second supply port 213b to the second discharge port 214b, and a flow area of opening the third supply port 213c to the third discharge port 214b by moving the spool valve element 217 inside the valve chamber 215, so that each flow rate of fluids discharged out of the first to third discharge ports 214a, 214b, and 214c (a flow rate distribution ratio) is regulated. Then, the fluids discharged out of the first to third discharge ports 214a, 214b, and 214c are merged in a merging point Y and output to the output pipe 4 which is connected to the merging point Y.

The fluid merged in the merging point Y and output to the output pipe 4 is the temperature control fluid for adjusting the temperature of the susceptor 1002. Specifically, the spool valve 21 adjusts the flow rate distribution ratio of the post-circulation temperature control fluid input from the input pipe 3 to the spool valve 21, the low-temperature fluid input from the input pipe for low-temperature fluid 5 to the spool valve 21, and the high-temperature fluid input from the input pipe for high-temperature fluid 7 to the spool valve 21, and thus adjusts the temperature of the temperature control fluid and outputs the temperature control fluid to the output pipe 4.

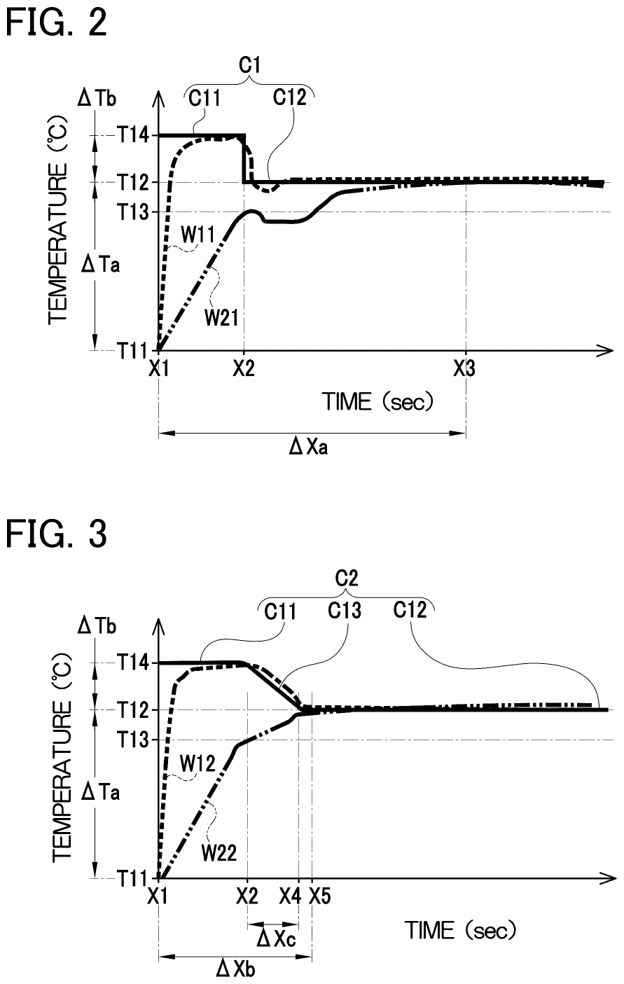

Adjustment of the flow rate distribution ratio performed by the spool valve 21 (i.e., adjustment of the temperature of the temperature control fluid output to the output pipe 4) is controlled based on a temperature control value (for example, see a waveform C1 (see FIG. 2)) that is created in the control device 1030 which will be explained below.

Herein, instead of using the spool valve 21, it is possible to perform temperature adjustment of the temperature control fluid by adjusting a flow rate by a poppet valve for the respective fluids of the post-circulation temperature control fluid, the low-temperature fluid, and the high-temperature fluid, for example. However, when a plurality of poppet valves are to be used, it could induce concerns about cost increase and increase in size of the unit 1. Further, the spool valve 21 of a small size has lower thermal capacity than the poppet valve, and thus heat of the temperature control fluid is hardly deprived by the spool valve 21. Accordingly, accuracy in temperature control of the temperature control fluid is improved. Therefore, it is preferable to perform temperature control of the temperature control fluid by use of the spool valve 21.

The first to third check valves 25, 26, and 27 are automatically adjusted their valve open degrees according to the flow rate distribution ratio that is controlled by the spool valve 21. Accordingly, the post-circulation temperature control fluid at the almost equal amount with the low-temperature fluid and the high-temperature fluid, which have been supplied to the spool valve 21, is returned to the cold chiller 1020 and the hot chiller 1010.

The unit 1 is provided with the control device 1030 to control operation of the temperature control system 1001, and the control device 1030 is connected to each sensor, each valve, and others of the unit 1 in a communicable manner. The control device 1030 includes a control board 1031, a pump driver 1033, and a valve controller 1032.

The control board 1031 creates the temperature control value (the waveform C1 (see FIG. 2)) based on a second temperature T12 and ΔTb which will be explained below. Then, temperature measured values measured by the temperature sensors 61, 62, 63, and 64 and pressure measured values measured by the first and second pressure sensors 51 and 52 are obtained by the unit 1 to create a valve operation signal so that the temperature of the temperature control fluid corresponds to the temperature control value and to transmit the signal to the unit 1 via the valve controller 1032. The unit 1 operates the spool valve 21 according to the valve operation signal to adjust the flow rate distribution ratio of the temperature control fluid, the low-temperature fluid, and the high-temperature fluid and adjust the temperature of the temperature control fluid in accordance with the temperature control value. As a result of this, the temperature of the temperature control fluid is performed with feedback control and made uniform.

Further, the control board 1031 obtains a flow rate measured value measured by the flow rate sensor 23 from the unit 1, creates a pump operation signal to regulate the flowrate of the temperature control fluid to a desired set flow rate, and transmits the signal to the unit 1 via the pump driver 1033. The unit 1 adjusts the flow rate of the temperature control fluid to the set flow rate by operating the pump 14 according to the pump operation signal. Therefore, the circulating flow rate of the temperature control fluid is feedback-controlled and made uniform.

### Temperature Control

A case of adjusting the temperature of the susceptor 1002 from a prescribed first temperature T11 to the prescribed second temperature T12, which is higher than the first temperature T11 by ΔTa, by the unit 1 having the above-mentioned configuration is now explained with FIG. 2. FIG. 2 is a graph showing a relation between the temperature of the temperature control fluid and the temperature of the post-circulation temperature control fluid (namely, the temperature of the susceptor 1002) in the flowrate control unit for temperature adjustment 1 according to the first embodiment. Herein, the case of adjusting the temperature of the susceptor 1002 from the prescribed first temperature T11 to the prescribed second temperature T12 means changing a processing condition from a first condition to a second condition for switching process gases when performing etching process to the wafer W, for example. To be more specific, the prescribed first temperature T11 represents a target temperature of the susceptor 1002 under the first condition, and the prescribed second temperature T12 represents a target temperature of the susceptor for the second condition. Other than that, when the semiconductor manufacturing device 1000 is at the timing of starting operation, the temperature of the susceptor 1002 is the first temperature T11, and the target temperature of the susceptor 1002 under an initial processing condition after starting operation is the second temperature T12.

Further, a third temperature T13 (one example of a prescribed threshold value) in FIG. 2 is a temperature at which the process under the second condition can be started even before the temperature of the susceptor 1002 reaches the second temperature T12 when the processing condition for the etching process is to be changed from the first condition to the second condition. The third temperature T13 is appropriately set by the processing condition of the etching process.

Further, the waveform C1 in FIG. 2 represents changes in the temperature control value for controlling the temperature of the temperature control fluid when the temperature of the susceptor 1002 is to be adjusted from the first temperature T11 to the second temperature T12. This temperature control value includes a first temperature control value C11 and a second temperature control value C12. The first temperature control value C11 is a temperature control value for controlling the temperature of the temperature control fluid to become a fourth temperature T14 which is higher than the second temperature T12 by ΔTb. Further, the second temperature control value C12 is a temperature control value for controlling the temperature of the temperature control fluid to become equal with the second temperature T12.

Further, a waveform W11 in FIG. 2 represents changes in the temperature of the temperature control fluid which is to be input to the susceptor 1002 by the flowrate control unit for temperature adjustment 1 when the temperature is controlled by the waveform C1.

The temperature of this temperature control fluid is a value measured by the first temperature sensor 64. The waveform W21 represents changes in the temperature of the post-circulation temperature control fluid that is measured by the second temperature sensor 61, namely, represents changes in the temperature of the susceptor 1002.

A time point X1 is a time when the temperature adjustment from the first temperature T11 to the second temperature T12 is started. At this time point X1, the temperature of the temperature control fluid input to the susceptor 1002 and the temperature of the post-circulation temperature control fluid (i.e., the temperature of the susceptor 1002) are both at the first temperature T11 as indicated with the waveform W11 and the waveform W21.

Then, from the time point X1, the temperature of the temperature control fluid is controlled by the first temperature control value C11. The first temperature control value C11 directs the temperature of the temperature control fluid to be controlled to the fourth temperature T14 that is higher than the second temperature T12 by ΔTb. Thereby, the temperature of the temperature control fluid input to the susceptor 1002 is adjusted to approach the fourth temperature T14 as indicated with the waveform W11 (first adjusting).

The temperature control fluid adjusted to the fourth temperature T14 heats the susceptor 1002, and thus the current temperature of the post-circulation temperature control fluid (i.e., the current temperature of the susceptor 1002) is increased as time elapses from the time point X1 as indicated by the waveform W21.

Then, on condition that the current temperature of the post-circulation temperature control fluid (i.e., the current temperature of the susceptor 1002) is increased to the third temperature T13 (a threshold value), the temperature control value is switched from the first temperature control value C11 to a second temperature control value C12 (a time point X2). The second temperature control value C12 directs the temperature of the temperature control fluid to be controlled to become equal with the second temperature T12. Thus, the temperature of the temperature control fluid input to the susceptor 1002 is adjusted to the second temperature T12 (second adjusting). The temperature of the temperature control fluid stably becomes the second temperature T12 after the temperature once overshot to the lower temperature than the second temperature T12 from the fourth temperature T14 as indicated with the waveform W11.

The current temperature of the post-circulation temperature control fluid (i.e., the current temperature of the susceptor 1002) is minutely lowered directly after the temperature control value is switched from the first temperature control value C11 to the second temperature control value C12 as indicated with the waveform W21. However, the susceptor 1002 is heated by the temperature control fluid that has been adjusted to the second temperature T12, so that the current temperature of the post-circulation temperature control fluid (i.e., the current temperature of the susceptor 1002) is increased again and reaches the second temperature T12 at the time point X3.

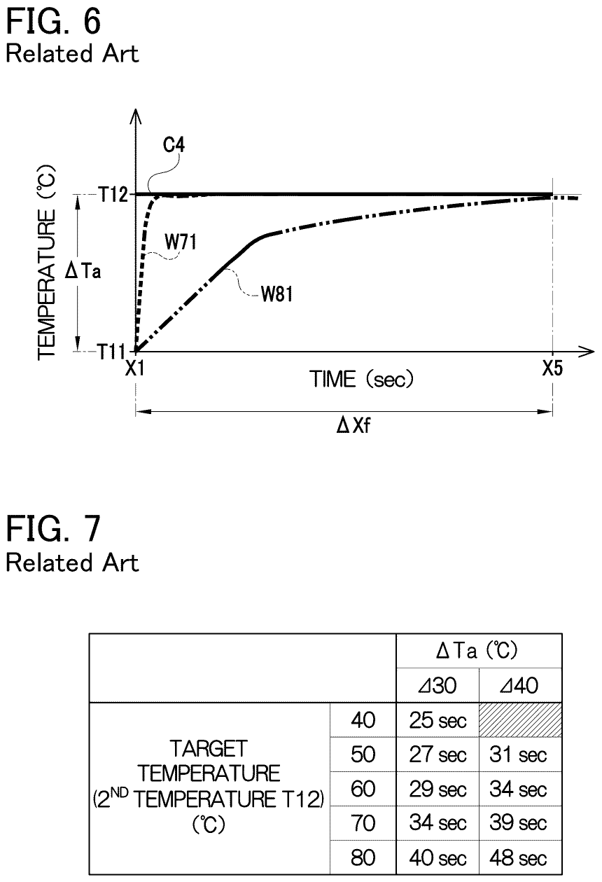

As mentioned above, the temperature of the temperature control fluid is adjusted by the first temperature control value C11, which directs the higher temperature than the second temperature T12, until the current temperature of the post-circulation temperature control fluid (i.e., the current temperature of the susceptor 1002) is increased to the third temperature T13 (the threshold value), and thus the temperature of the susceptor 1002 can be increased from the first temperature T11 to the second temperature T12 at high speed. A period of time for the temperature of the susceptor 1002 to reach the second temperature T12 (a period of time ΔXa from the time point X1 to the time point X3) is as much as about 60% of the period of time ΔXf (see FIG. 6) for increasing the temperature of the susceptor to the second temperature T12 by the flowrate control unit for temperature adjustment according to the conventional art. Herein, the higher the fourth temperature T14 (the first temperature control value C11) is set than the second temperature T12 (namely, as the value ΔTb is larger), the faster the temperature of the susceptor 1002 is increased from the first temperature T11 to the second temperature T12. Accordingly, ΔTb is appropriately set according to a target period of time for increasing the temperature of the susceptor 1002 from the first temperature T11 to the second temperature T12, and the fourth temperature T14 (the first temperature control value C11) is determined by the thus set value of ΔTb and the second temperature T12.

### Second Embodiment

Next, a flowrate control unit for temperature adjustment according to a second embodiment is explained. The flowrate control unit for temperature adjustment according to the second embodiment has the same configuration with the unit 1 according to the first embodiment while only a temperature control value for controlling a temperature of a temperature control fluid is different.

In the first embodiment, directly after the temperature control value is switched from the first temperature control value C11 to the second temperature control value C12 at the time point X2, the current temperature of the post-circulation temperature control fluid (i.e., the current temperature of the susceptor 1002) could be lowered below the third temperature T13 (the threshold value). When the processing condition of the etching process is to be switched from the first condition to the second condition, the third temperature T13 (the threshold value) has been set as a temperature at which the process under the second condition is allowed to start even before the temperature of the susceptor 1002 reaches the second temperature T12. Specifically, the process under the second condition is to be started at the time point X2 when the current temperature of the post-circulation temperature control fluid (i.e., the current temperature of the susceptor 1002) reaches the third temperature T13 (the threshold value), but, after the process has started, if the current temperature of the post-circulation temperature control fluid (i.e., the current temperature of the susceptor 1002) is lowered below the third temperature T13 (the threshold value), which is a prerequisite for starting the process, the etching process could be failed, and it is not preferable.

To address this, for example, it is preferable to adjust the temperature of the susceptor 1002 by the temperature control value (the waveform C2) as indicated in FIG. 3. FIG. 3 is a graph showing a relation between the temperature of the temperature control fluid and the temperature of the post-circulation temperature control fluid (i.e., the temperature of the susceptor 1002) in the flowrate control unit for temperature adjustment according to the second embodiment. Herein, the first temperature T11, the second temperature T12, the third temperature T13, and the fourth temperature T14 in FIG. 3 are identical with the first temperature T11, the second temperature T12, the third temperature T13, and the fourth temperature T14 in FIG. 2. Further, a value ΔTb as a gap between the second temperature T12 and the fourth temperature T14 is identical with ΔTb in FIG. 2.

The waveform C2 represents changes in the temperature control value for controlling the temperature of the temperature control fluid when the temperature of the susceptor 1002 is to be adjusted from the first temperature T11 to the second temperature T12. This temperature control value is created by the control board 1031 based on the second temperature T12, the value ΔTb explained later, and a value ΔXc. Further, the temperature control value includes the first temperature control value C11, the second temperature control value C12, and a third temperature control value C13. The first temperature control value C11 and the second temperature control value C12 are identical with the ones in the first embodiment. The third temperature control value C13 will be explained later.

The waveform W12 represents the changes in the temperature of the temperature control fluid that is input to the susceptor 1002 by the flowrate control unit for temperature adjustment 1 while the temperature is controlled by the waveform C2. Herein, the temperature of this temperature control fluid is a value measured by the first temperature sensor 64. The waveform W22 represents changes in the temperature of the post-circulation temperature control fluid that is measured by the second temperature sensor 61, namely represents changes in the temperature of the susceptor 1002.

At the time point X1 to start adjusting the temperature from the first temperature T11 to the second temperature T12, the temperature of the temperature control fluid input into the susceptor 1002 and the temperature of the post-circulation temperature control fluid (i.e., the temperature of the susceptor 1002) are both the first temperature T11 as indicated with the waveform W12 and the waveform W22.

Then, from the time point X1, the temperature of the temperature control fluid is controlled by the first temperature control value C11. Thus, the temperature of the temperature control fluid input into the susceptor 1002 is adjusted to come to the fourth temperature T14 as indicated with the waveform W12 (first adjusting).

The susceptor 1002 is heated by the temperature control fluid that has been adjusted to the fourth temperature T14, and accordingly, the current temperature of the post-circulation temperature control fluid (i.e., the current temperature of the susceptor 1002) is increased as time elapses from the time point X1 as indicated with the waveform W22.

Then, on condition that the current temperature of the post-circulation temperature control fluid (i.e., the current temperature of the susceptor 1002) has been increased to the third temperature T13 (the threshold value), the temperature control value for controlling the temperature of the temperature control fluid is switched from the first temperature control value C11 to the second temperature control value C12 (the time point X2). This switching from the first temperature control value C11 to the second temperature control value C12 is performed via the third temperature control value C13. The third temperature control value C13 gradually changes the directing temperature from the first temperature control value C11 directing the fourth temperature T14 to the second temperature control value C12 directing the second temperature T12 during a period of time from the time point X2 to the time point X4.

The temperature control value is gradually changed by the third temperature control value C13, and thus the temperature of the temperature control fluid is smoothly changed toward the second temperature T12 as indicated with the waveform W12. The temperature of the temperature control fluid is thus adjusted (second adjusting), so that the current temperature of the post-circulation temperature control fluid (i.e., the current temperature of the susceptor 1002) is smoothly increased to the second temperature T12 without showing a behavior of temperature fall (see the waveform W21 in FIG. 2) due to switching of the temperature control value as indicated with the waveform W22. Accordingly, failure in the etching process can be prevented.

Herein, an inclination of the temperature control value C13 in FIG. 3 is determined by ΔTb as a gap between the second temperature T12 and the fourth temperature T14 and by a period of time for gradually changing the temperature (i.e., a period of time ΔXc from the time point X2 to the time point X4). When the period of time ΔXc is too short and the inclination of the third temperature control value C13 becomes steep, the current temperature of the post-circulation temperature control fluid (i.e., the current temperature of the susceptor 1002) is lowered by switching the temperature control value, which could cause decline in the current temperature lower than the third temperature T13 (the threshold value). Accordingly, the period of time ΔXc is sought by experiments such that the current temperature of the post-circulation temperature control fluid (i.e., the current temperature of the susceptor 1002) is not lowered below the third temperature T13 (the threshold value) by switching of the temperature control values. The period of time ΔXc is thus appropriately set to be equal to or longer than the value obtained by the experiments.

Further, the current temperature of the post-circulation temperature control fluid (i.e., the current temperature of the susceptor 1002) has reached the second temperature T12 at the time point X5 as indicated with the waveform W22. The period of time until the temperature of the susceptor 1002 reaches the second temperature T12 (the period of time ΔXb from the time point X1 to the time point X5) is as long as about 25% to 40% of the period of time ΔXf (see FIG. 6) which is required for increasing the temperature of the susceptor to the second temperature T12 by the flowrate control unit for temperature adjustment according to the conventional art. In other words, according to the temperature control value (the waveform C2) in the second embodiment, the temperature of the susceptor 1002 can be increased from the first temperature T11 to the second temperature T12 at more high-speed than the unit 1 according to the first embodiment.

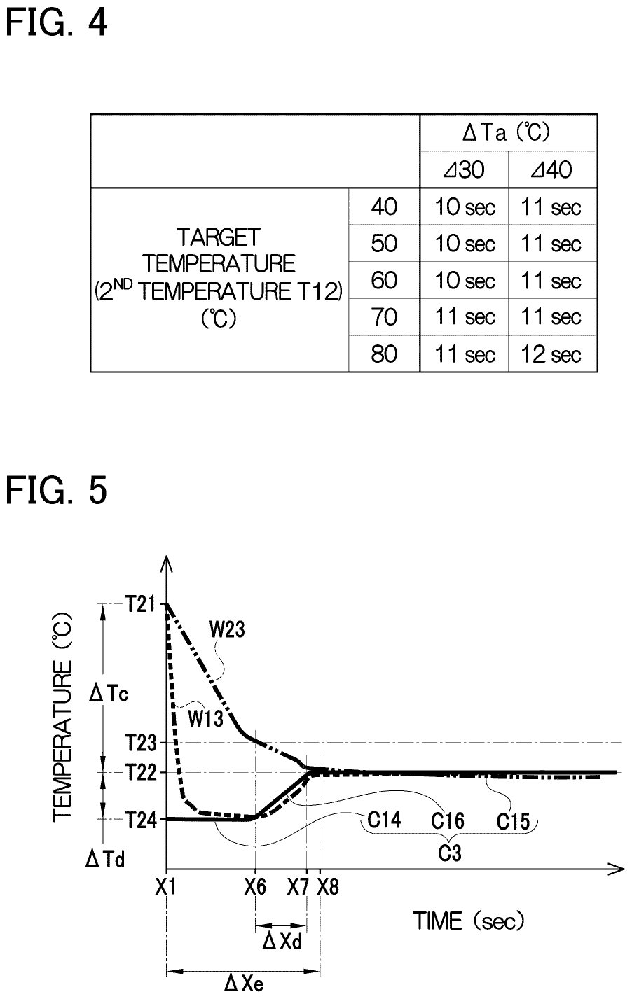

Herein, specific numerical values of the period of time ΔXb are illustrated in FIG. 4. FIG. 4 is a table summarizing the period of time ΔXb required for the temperature of the susceptor 1002 (the temperature of the post-circulation temperature control fluid) to reach the second temperature T12 at each value of ΔTa as a gap between the first temperature T11 and the second temperature T12. For example, a value of 10 seconds when ΔTa is 30° C. and the second temperature T12 is 40° C. means that the period of time ΔXb is 10 seconds when the temperature of the susceptor 1002 is increased by 30° C. to reach 40° C. (namely, when the temperature of the susceptor 1002 is increased from 10° C. to 40° C.). The table illustrates ΔTa in cases of 30° C. and 40° C. because ΔTa is mostly 30 to 40° C. in the general processing condition for the etching process, but that is only an illustration.

When ΔTa is 30° C. or 40° C., the period of time ΔXb is in a range of 10 to 12 seconds as shown in FIG. 4. These values are about 25 to 40% of the period of time ΔXf that is 25 to 48 seconds in case of increasing the temperature of the susceptor by the flowrate control unit for temperature adjustment according to the conventional art to the second temperature T12 (see FIG. 7).

The first embodiment and the second embodiment have the identical configuration of the unit 1 but has different arrangement of the temperature control value for controlling the temperature of the temperature control fluid, and thus depending on a configuration of a program, the first embodiment and the second embodiment may be switchable. Namely, it may be selectable to determine whether the temperature control value is gradually changed from the first temperature control value C11 corresponding to the fourth temperature T14 to the second temperature control value C12 corresponding to the second temperature T12 (in other words, whether the temperature of the temperature control fluid is controlled by the temperature control value according to the waveform C1 or the temperature of the temperature control fluid is controlled by the temperature control value according to the waveform C2).

Further, the temperature control of the temperature control fluid by the above-mentioned waveform C1 or the waveform C2 may be performed when the value ΔTa exceeds a prescribed threshold value. For example, in a case that ΔTa is one specified value (referred as a value A) or less, when the susceptor 1002 is heated by the temperature control fluid at the fourth temperature T14 and overshot to the higher temperature than the second temperature T12 as targeted, the control device 1030 determines whether the temperature control of the temperature control fluid is performed by the waveform C1 or the waveform C2 with the value A set as the threshold value. Specifically, when ΔTa exceeds the value A, the temperature control of the temperature control fluid is performed by the waveform C1 or the waveform C2. When ΔTa is the value A or less, as similar to the conventional art, controlling the temperature of the temperature control fluid to be equal with the second temperature T12 is started at the time point X1 (see FIG. 6).

### Third Embodiment

The above-mentioned first embodiment and second embodiment are explained for a case of increasing the temperature of the susceptor 1002, but when the processing condition is to be changed for switching the process gases, a case of lowering the temperature of the susceptor 1002 is naturally considered. When the temperature of the susceptor 1002 is to be lowered, for example, the temperature of the temperature control fluid is controlled by the temperature control value (a waveform C3) shown in FIG. 5 to adjust the temperature of the susceptor 1002.

FIG. 5 is a graph showing a relation of the temperature of the temperature control fluid and the temperature of the post-circulation temperature control fluid (i.e., the temperature of the susceptor 1002) in the flowrate control unit for temperature adjustment 1 according to a third embodiment. The graph explains a case of adjusting the temperature of the susceptor 1002 from the prescribed first temperature T21 to the prescribed second temperature T22 which is lower than the first temperature T21 by ΔTc.

The waveform C3 in FIG. 5 represents changes in the temperature control value for controlling the temperature of the temperature control fluid when the temperature of the susceptor 1002 is to be adjusted from the first temperature T21 to the second temperature T22. This temperature control value is created by the control board 1031 based on the second temperature T22, the value ΔTd, and the value ΔXd. Further, the temperature control value includes the first temperature control value C14, the second temperature control value C15, and the third temperature control value C16. The first temperature control value C14 is the temperature control value for controlling the temperature of the temperature control fluid to the fourth temperature T24 which is lower than the second temperature T22 only by ΔTd. The second temperature control value C15 is the temperature control value for controlling the temperature of the temperature control fluid to be equal with the second temperature T22. The third temperature control value C16 is the temperature control value to gradually change the directing temperature from the fourth temperature T24 directed by the first temperature control value C14 to the second temperature T22 which is directed by the second temperature control value C15.

Further, a waveform W13 in FIG. S represents temperature changes when the temperature of the temperature control fluid input into the susceptor 1002 by the flowrate control unit for temperature adjustment is controlled by the waveform C3. Herein, the temperature of this temperature control fluid is a value measured by the first temperature sensor 64. A waveform W23 represents temperature changes in the post-circulation temperature control fluid which is measured by the second temperature sensor 61, namely, represents temperature changes in the susceptor 1002.

At the time point X1 of starting the temperature control from the first temperature T21 to the second temperature T22, the temperature of the temperature control fluid input into the susceptor 1002 and the temperature of the post-circulation temperature control fluid (i.e., the temperature of the susceptor 1002) are both the first temperature T21 as indicated with the waveform W13 and the waveform W23.

Then, from the time point X1, the temperature of the temperature control fluid is controlled by the first temperature control value C14. Thus, the temperature of the temperature control fluid input to the susceptor 1002 is adjusted to come to the fourth temperature T24 as indicated with the waveform W13 (first adjusting).

The temperature control fluid adjusted to the fourth temperature T24 cools the susceptor 1002, and thus the current temperature of the post-circulation temperature control fluid (i.e., the current temperature of the susceptor 1002) is lowered as time elapses from the time point X1 as indicated with the waveform W23.

Then, on condition that the current temperature of the post-circulation temperature control fluid (i.e., the current temperature of the susceptor 1002) is lowered to the third temperature T23 (the threshold value), the temperature control value for controlling the temperature of the temperature control fluid is switched from the first temperature control value C14 to the second temperature control value C15 (the time point X6). Switching from the first temperature control value C14 to the second temperature control value C15 is performed via the third temperature control value C16. The third temperature control value C16 gradually changes the directing temperature from the first temperature control value C14 directing the fourth temperature T24 to the second temperature control value C15 directing the second temperature T22 in a period of time from the time point X6 to the time point X7. Herein, the inclination of the third temperature control value C16 is determined by ΔTd as a gap between the second temperature T22 and the fourth temperature T24 and the period of time for gradually changing (the period of time ΔXd from the time point X6 to the time point X7).

Herein, an inclination of the third temperature control value C16 in FIG. S is determined by ΔTd as a gap between the second temperature T22 and the fourth temperature T24 and by a period of time for gradually changing (i.e., a period of time ΔXd from the time point X6 to the time point X7). When the period of time ΔXd is too short and the inclination of the third temperature control value C16 becomes steep, the current temperature of the post-circulation temperature control fluid (i.e., the current temperature of the susceptor 1002) is increased by switching the temperature control value, which could cause excess of the current temperature over the third temperature T23 (the threshold value). This could cause failure in the etching process. Accordingly, the period of time ΔXd is sought by experiments such that the current temperature of the post-circulation temperature control fluid (i.e., the current temperature of the susceptor 1002) does not exceed the third temperature T23 (the threshold value) by switching the temperature control values. The period of time ΔXd is thus appropriately set to be equal to or longer than the value obtained by the experiments.

By the third temperature control value C16, the directing temperature is gradually changed from the fourth temperature T24 directed by the first temperature control value C14 to the second temperature T22 directed by the second temperature value C15. Accordingly, the temperature of the temperature control fluid smoothly changes toward the second temperature T22 as indicated with the waveform W13.

Then, the susceptor 1002 is cooled by the temperature control fluid adjusted to the second temperature T22, and the current temperature of the post-circulation temperature control fluid (i.e., the current temperature of the susceptor 1002) reaches the second temperature T22 at the time point X8 as indicated with the waveform W23.

As mentioned above, the temperature of the temperature control fluid is adjusted by the first temperature control value C14 directing the lower temperature than the second temperature T22 until the current temperature of the post-circulation temperature control fluid (i.e., the current temperature of the susceptor 1002) is lowered to the third temperature T23 (the threshold value). Accordingly, the temperature of the susceptor 1002 can be lowered from the first temperature T21 to the second temperature T22 at high speed. Herein, the lower the fourth temperature T24 (the first temperature control value C14) is set than the second temperature T22 (in other words, as the value ΔTd is larger), the faster the temperature of the susceptor 1002 is lowered from the first temperature T21 to the second temperature T22. Therefore, ΔTd is appropriately set in accordance with a target period of time for lowering the temperature of the susceptor 1002 from the first temperature T21 to the second temperature T22. Setting of this ΔTd determines the fourth temperature T24 (the first temperature control value C14).

Herein, switching from the first temperature control value C14 to the second temperature control value C15 at the time point X6 may be performed without going through the third temperature control value C16 as indicated with the waveform C1 in FIG. 2.

Further, the temperature control of the temperature control fluid by the above-mentioned waveform C3 may be performed when the value ΔTc exceeds a prescribed threshold value. For example, in case of ΔTc being a specified value (referred as a value B) or less, when the temperature control fluid at the fourth temperature T24 cools the susceptor 1002 and the susceptor 1002 is caused to overshoot to a lower temperature than the targeted second temperature T22, the control device 1030 determines whether the temperature control of the temperature control fluid is performed by the waveform C3 with the specified value B set as a threshold value. Specifically, when ΔTc exceeds the value B, the temperature control of the temperature control fluid by the waveform C3 is carried out, and when ΔTc becomes the value B or less, as similar to the conventional art, controlling the temperature of the temperature control fluid to be equal with the second temperature T22 is started at the time point X1.

Herein, the first embodiment, the second embodiment, and the third embodiment have the identical configuration and differ from one another in the temperature control values for controlling the temperature of the temperature control fluid. Therefore, the control device 1030 may automatically determine whether the temperature control of the temperature control fluid by use of the waveform C3 is performed depending on increasing or reducing the temperature of the susceptor. Specifically, when the current temperature of the post-circulation temperature control fluid (the current temperature of the susceptor 1002) is lower than the targeted second temperature T12, T22, the temperature of the susceptor needs to be increased, and thus the temperature control of the temperature control fluid is performed by use of the waveform C1 or the waveform C2. When the current temperature of the post-circulation temperature control fluid (the current temperature of the susceptor 1002) is higher than the targeted second temperature T12, T22, the temperature of the susceptor needs to be lowered, and thus the temperature control of the temperature control fluid is performed by use of the waveform C3.

As explained above, the flowrate control unit for temperature adjustment 1 is characterized as a flowrate control unit 1 for temperature adjustment to adjust a temperature of a susceptor 1002 from a prescribed first temperature T11 to a prescribed second temperature T12 by circulating a temperature control fluid through the susceptor 1002 provided in a semiconductor manufacturing device 1000, wherein the unit 1 comprises: an output pipe 4 to output the temperature control fluid to the susceptor 1002; a first temperature measuring part (a first temperature sensor 64) to measure a temperature of the temperature control fluid output from the output pipe 4; an input pipe 3 to input a post-circulation temperature control fluid, which is the temperature control fluid output from the output pipe 4 to the susceptor 1002 and circulated through the susceptor 1002; a control device 1030 to create a temperature control value (a waveform C1 or a waveform C2) for directing the temperature of the temperature control fluid output from the output pipe 4; a fluid control part 24 to adjust the temperature of the temperature control fluid output from the output pipe 4 based on the temperature control value (the waveform C1 or the waveform C2); and a second temperature measuring part (a second temperature sensor 61) to measure a current temperature of the post-circulation temperature control fluid, wherein the temperature control value (the waveform C1 or the waveform C2) includes a prescribed first temperature control value C11 for directing a temperature (a fourth temperature T14) higher than the second temperature T12 and a prescribed second temperature control value C12 for directing the temperature equal to the second temperature T12, and the fluid control part 24 is configured to: perform first adjusting to adjust the temperature of the temperature control fluid by the first temperature control value C11 until a current temperature increases to a prescribed threshold value (a third temperature T13), which is lower than the second temperature T12, when the current temperature is lower than the second temperature T12; and perform second adjusting to adjust the temperature of the temperature control fluid by the second temperature control value C12 when the current temperature increases to the threshold value (the third temperature T13).

Further, in the above-mentioned flowrate control unit for temperature adjustment 1, preferably, the temperature control value (the waveform C2) in the second adjusting gradually changes from the first temperature control value C11 to the second temperature control value C12 (the third temperature control value C13).

Further, in the above-mentioned flowrate control unit for temperature adjustment 1, preferably, the fluid control part 24 includes a low-temperature pipe (an input pipe for low-temperature fluid 5 and an output pipe for low-temperature fluid 6) through which a low-temperature fluid for lowering the temperature of the temperature control fluid flows, a high-temperature pipe (an input pipe for high-temperature fluid 7 and an output pipe for high-temperature fluid 8) through which a high-temperature fluid for increasing the temperature of the temperature control fluid flows, and a spool valve 21 connected to the output pipe 4, the input pipe 3, the low-temperature pipe (an input pipe for low-temperature fluid 5 and an output pipe for low-temperature fluid 6), and the high-temperature pipe (an input pipe for high-temperature fluid 7 and an output pipe for high-temperature fluid 8), and the fluid control part 24 is configured to control a flow rate distribution ratio of the post-circulation temperature control fluid, the low-temperature fluid, and the high-temperature fluid to adjust the temperature of the temperature control fluid output from the output pipe 4.

Further, in the above-mentioned flowrate control unit for temperature adjustment 1, preferably, the input pipe 3 includes a pump 14 to circulate the temperature control fluid, and the second temperature measuring part (the second temperature sensor 61) is provided on an upstream side of the pump 14.

Further, in the above-mentioned flowrate control unit for temperature adjustment 1, preferably, the flowrate control unit 1 for temperature adjustment further comprises a joint pipe (for example, a first joint pipe 1005) joining the input pipe 3 and the susceptor 1002, and the second temperature measuring part (the second temperature sensor 61) is provided in the joint pipe (the first joint pipe 1005).

The above-mentioned flowrate control unit for temperature adjustment 1 measures the current temperature of the post-circulation temperature control fluid by the second temperature measuring part (the second temperature sensor 61). The post-circulation temperature control fluid is a temperature control fluid after having circulated through the susceptor 1002, and thus the temperature can be identified with the temperature of the susceptor 1002. For example, the susceptor 1002 in an RIE plasma processing device, it is difficult to directly measure the temperature due to influence of process gas that has been brought into a plasma state, and others. To address this, by measuring the current temperature of the post-circulation temperature control fluid that has circulated through the susceptor 1002, it is possible to stably monitor the temperature of the susceptor 1002.

Further, when the current temperature of the post-circulation temperature control fluid (namely, the temperature of the susceptor 1002) is lower than the second temperature T12, the above-mentioned flowrate control unit for temperature adjustment 1 is configured such that the unit 1 adjusts the temperature of the temperature control fluid (the first adjusting) by the prescribed first temperature control value C11 directing the higher temperature (the fourth temperature T14) than the second temperature T12 until the current temperature of the post-circulation temperature control fluid (the temperature of the susceptor 1002) increases to the prescribed threshold value (the third temperature T13) which is lower than the second temperature T12 so that the temperature of the susceptor 1002 is adjusted to the prescribed second temperature T12. Accordingly, the susceptor 1002 is heated by the temperature control fluid at the higher temperature than the second temperature T12, and thus the temperature of the susceptor 1002 is increased to the second temperature T12 at high speed. Then, when the current temperature of the post-circulation temperature control fluid (the temperature of the susceptor 1002) is increased to the threshold value (the third temperature T13), the temperature of the temperature control fluid is adjusted (the second adjusting) by the second temperature control value C12 directing the equal temperature with the second temperature T12, so that the temperature of the susceptor 1002 can be stabilized at the second temperature T12.

Further, the flowrate control unit for temperature adjustment 1 according to another aspect of the present invention is characterized as a flowrate control unit 1 for temperature adjustment to adjust a temperature of a susceptor 1002 from a prescribed first temperature T21 to a prescribed second temperature T22 by circulating a temperature control fluid through the susceptor 1002 provided in a semiconductor manufacturing device 1000, wherein the unit 1 comprises: an output pipe 4 to output the temperature control fluid to the susceptor 1002; a first temperature measuring part (a first temperature sensor 64) to measure a temperature of the temperature control fluid output from the output pipe 4; an input pipe 3 to input a post-circulation temperature control fluid, which is a temperature control fluid output from the output pipe 4 to the susceptor 1002 and circulated through the susceptor 1002; a control device 1030 to create a temperature control value (a waveform C3) for directing the temperature of the temperature control fluid output from the output pipe 4; a fluid control part 24 to adjust the temperature of the temperature control fluid output from the output pipe 4 based on the temperature control value the waveform C3);

and a second temperature measuring part (a second temperature sensor 61) to measure a current temperature of the post-circulation temperature control fluid, wherein the temperature control value (the waveform C3) includes a prescribed first temperature control value C14 for directing a temperature (a fourth temperature T24) lower than the second temperature T22 and a prescribed second temperature control value C15 for directing the temperature equal to the second temperature T22, and the fluid control part 24 is configured to: perform first adjusting to adjust the temperature of the temperature control fluid by the first temperature control value C14 until the current temperature is lowered to a prescribed threshold value (a third temperature T23), which is higher than the second temperature T22, when the current temperature is higher than the second temperature T22; and perform second adjusting to adjust the temperature of the temperature control fluid by the second temperature control value C15 when the current temperature is lowered to the threshold value (the third temperature T23.

Further, in the above-mentioned flowrate control unit for temperature adjustment 1, preferably, the temperature control value in the second adjusting gradually changes from the first temperature control value C14 to the second temperature control value C15 (a third temperature control value C16).

Further, in the above-mentioned flowrate control unit for temperature adjustment 1, preferably, the fluid control part 24 includes a low-temperature pipe (an input pipe for low-temperature fluid 5 and an output pipe for low-temperature fluid 6) through which a low-temperature fluid for lowering the temperature of the temperature control fluid flows, a high-temperature pipe (an input pipe for high-temperature fluid 7 and an output pipe for high-temperature fluid 8) through which a high-temperature fluid for increasing the temperature of the temperature control fluid flows, and a spool valve 21 connected to the output pipe 4, the input pipe 3, the low-temperature pipe (an input pipe for low-temperature fluid 5 and an output pipe for low-temperature fluid 6), and the high-temperature pipe (an input pipe for high-temperature fluid 7 and an output pipe for high-temperature fluid 8), and the fluid control part 24 is configured to control a flow rate distribution ratio of the post-circulation temperature fluid, the low-temperature fluid, and the high-temperature fluid to adjust the temperature of the temperature control fluid output from the output pipe 4.

Further, in the above-mentioned flowrate control unit for temperature adjustment 1, preferably, the input pipe 3 includes a pump 14 to circulate the temperature control fluid, and the second temperature measuring part (the second temperature sensor 61) is provided on an upstream side of the pump 14.

Further, in the above-mentioned flowrate control unit for temperature adjustment 1, preferably, the flowrate control unit 1 for temperature adjustment further comprises a joint pipe (for example, a first joint pipe 1005) joining the input pipe 3 and the susceptor 1002, and the second temperature measuring part (the second temperature sensor 61) is provided in the joint pipe (the first joint pipe 1005).

The above-mentioned flowrate control unit for temperature adjustment 1 is configured such that, when the current temperature of the post-circulation temperature control fluid (namely, the temperature of the susceptor 1002) is higher than the second temperature T22, the unit 1 adjusts the temperature of the temperature control fluid (the first adjusting) by the prescribed first temperature control value C14 directing the lower temperature (the fourth temperature T24) than the second temperature T22 until the current temperature of the post-circulation temperature control fluid (the temperature of the susceptor 1002) is lowered to the prescribed threshold value (the third temperature T23) which is higher than the second temperature T22, so that the temperature of the susceptor 1002 is adjusted to the second temperature T22. Accordingly, the susceptor 1002 is cooled by the temperature control fluid at the lower temperature than the second temperature T22, so that the temperature of the susceptor 1002 is lowered to the second temperature T22 at high speed. Then, when the current temperature of the post-circulation temperature control fluid (the temperature of the susceptor 1002) is lowered to the threshold value (the third temperature T23), the temperature of the temperature control fluid is adjusted (the second adjusting) by the second temperature control value C15 directing the equal temperature with the second temperature T22, so that the temperature of the susceptor 1002 can be stabilized to the second temperature T22.

Further, the semiconductor manufacturing device 1000 according to one aspect of the present invention is characterized to comprise the susceptor 1002 and the above-mentioned flowrate control unit for temperature adjustment 1 connected to the susceptor 1002, and thus the temperature control of the susceptor 1002 can be performed at high speed.

The above embodiments are only illustration and give no any limitation to the present invention. Accordingly, the present invention can naturally be made with various improvements and modifications without departing from the scope of the invention. For example, the above embodiments are exemplified with the unit 1 applied to the semiconductor manufacturing device 1, but alternatively, the unit 1 may be applied for temperature control in devices other than the semiconductor manufacturing device 1000.

### REFERENCE SIGNS LIST

1 Flowrate control unit for temperature adjustment
3 Input pipe
4 Output pipe
24 Fluid control part
61 Second temperature sensor (one example of a second temperature measuring part)
64 First temperature sensor (one example of a first temperature measuring part)
1002 Susceptor
1030 Control device
C1 Temperature control value
C11 First temperature control value
C12 Second temperature control value
T11 First temperature
T12 Second temperature

1. A flowrate control unit for temperature adjustment to adjust a temperature of a susceptor from a prescribed first temperature to a prescribed second temperature by circulating a temperature control fluid through the susceptor provided in a semiconductor manufacturing device, wherein
the unit comprises:
an output pipe to output the temperature control fluid to the susceptor;
a first temperature measuring part to measure a temperature of the temperature control fluid output from the output pipe;
an input pipe to input a post-circulation temperature control fluid, which is the temperature control fluid output from the output pipe to the susceptor and circulated through the susceptor;
a control device to create a temperature control value for directing the temperature of the temperature control fluid output from the output pipe;
a fluid control part to adjust the temperature of the temperature control fluid output from the output pipe based on the temperature control value; and
a second temperature measuring part to measure a current temperature of the post-circulation temperature control fluid,
wherein
the temperature control value includes a prescribed first temperature control value for directing a temperature higher than the second temperature and a prescribed second temperature control value for directing the temperature equal to the second temperature,
the fluid control part is configured to:
perform first adjusting to adjust the temperature of the temperature control fluid by the first temperature control value until a current temperature increases to a prescribed threshold value, which is lower than the second temperature, when the current temperature is lower than the second temperature; and
perform second adjusting to adjust the temperature of the temperature control fluid by the second temperature control value when the current temperature increases to the threshold value
the temperature control value in the second adjusting has a gradual change from the first temperature control value to the second temperature control value, and
the gradual change is set at an inclination that keeps the current temperature from falling below the threshold value.

2. A flowrate control unit for temperature adjustment to adjust a temperature of a susceptor from a prescribed first temperature to a prescribed second temperature by circulating a temperature control fluid through the susceptor provided in a semiconductor manufacturing device, wherein
the unit comprises:
an output pipe to output the temperature control fluid to the susceptor;
a first temperature measuring part to measure a temperature of the temperature control fluid output from the output pipe;
an input pipe to input a post-circulation temperature control fluid, which is a temperature control fluid output from the output pipe to the susceptor and circulated through the susceptor;
a control device to create a temperature control value for directing the temperature of the temperature control fluid output from the output pipe;
a fluid control part to adjust the temperature of the temperature control fluid output from the output pipe based on the temperature control value; and
a second temperature measuring part to measure a current temperature of the post-circulation temperature control fluid,
wherein
the temperature control value includes a prescribed first temperature control value for directing a temperature lower than the second temperature and a prescribed second temperature control value for directing the temperature equal to the second temperature,
the fluid control part is configured to:
perform first adjusting to adjust the temperature of the temperature control fluid by the first temperature control value until the current temperature is lowered to a prescribed threshold value, which is higher than the second temperature, when the current temperature is higher than the second temperature; and
perform second adjusting to adjust the temperature of the temperature control fluid by the second temperature control value when the current temperature is lowered to the threshold value
the temperature control value in the second adjusting has a gradual change from the first temperature control value to the second temperature control value, and
the gradual change is set at an inclination that keeps the current temperature from exceeding the threshold value.

3. (canceled)

4. (canceled)

5. The flowrate control unit for temperature adjustment according to claim 1, wherein
the fluid control part includes a low-temperature pipe through which a low-temperature fluid for lowering the temperature of the temperature control fluid flows, a high-temperature pipe through which a high-temperature fluid for increasing the temperature of the temperature control fluid flows, and a spool valve connected to the output pipe, the input pipe, the low-temperature pipe, and the high-temperature pipe, and
the fluid control part is configured to control a flow rate distribution ratio of the post-circulation temperature control fluid, the low-temperature fluid, and the high-temperature fluid to adjust the temperature of the temperature control fluid output from the output pipe.

6. The flowrate control unit for temperature adjustment according to claim 1, wherein
the input pipe includes a pump to circulate the temperature control fluid, and
the second temperature measuring part is provided on an upstream side of the pump.

7. The flowrate control unit for temperature adjustment according to claim 1, wherein
the flowrate control unit for temperature adjustment further comprises a joint pipe joining the input pipe and the susceptor, and
the second temperature measuring part is provided in the joint pipe.

8. A semiconductor manufacturing device provided with the susceptor and the flowrate control unit for temperature adjustment according to claim 1, which is connected to the susceptor.

9. The flowrate control unit for temperature adjustment according to claim 2, wherein
the fluid control part includes a low-temperature pipe through which a low-temperature fluid for lowering the temperature of the temperature control fluid flows, a high-temperature pipe through which a high-temperature fluid for increasing the temperature of the temperature control fluid flows, and a spool valve connected to the output pipe, the input pipe, the low-temperature pipe, and the high-temperature pipe, and
the fluid control part is configured to control a flow rate distribution ratio of the post-circulation temperature control fluid, the low-temperature fluid, and the high-temperature fluid to adjust the temperature of the temperature control fluid output from the output pipe.

10. The flowrate control unit for temperature adjustment according to claim 2, wherein
the input pipe includes a pump to circulate the temperature control fluid, and
the second temperature measuring part is provided on an upstream side of the pump.

11. The flowrate control unit for temperature adjustment according to claim 2, wherein
the flowrate control unit for temperature adjustment further comprises a joint pipe joining the input pipe and the susceptor, and
the second temperature measuring part is provided in the joint pipe.

12. A semiconductor manufacturing device provided with the susceptor and the flowrate control unit for temperature adjustment according to claim 2, which is connected to the susceptor.
